(19) United States
(12) Patent Application Publication
(10) Pub. No.: US 2025/0324759 A1
(43) Pub. Date: Oct. 16, 2025

(54) DISPLAY SUBSTRATE AND DISPLAY DEVICE

(71) Applicant: Sharp Display Technology Corporation, Kameyama City (JP)

(72) Inventor: Hiroshi MATSUKIZONO, Kameyama City (JP)

(21) Appl. No.: 19/098,276

(22) Filed: Apr. 2, 2025

(30) Foreign Application Priority Data
Apr. 15, 2024 (JP) 2024-065377

(51) Int. Cl. H10D 86/40; G02F 1/1333; G02F 1/1343; G02F 1/1368; G06F 3/041; G06F 3/044

(52) U.S. Cl. CPC H10D 86/441; G02F 1/13338; G02F 1/134309; G02F 1/1368; G06F 3/0412; G06F 3/04164; G06F 3/0446

(57) ABSTRACT

A display substrate includes a plurality of first wires; a plurality of second wires; a plurality of first thin-film transistors each connected to any of the plurality of first wires and any of the plurality of second wires; a plurality of pixel electrodes each connected to a corresponding one of the plurality of first thin-film transistors; a signal supply unit that supplies image signals to the plurality of second wires; and a plurality of second thin-film transistors constituting a demultiplexer circuit that distributes, to the plurality of second wires, the image signals supplied from the signal supply unit.

### BACKGROUND

### 1. Field

The present disclosure relates to a display substrate and a display device.

### 2. Description of the Related Art

Conventionally, there has been known a display substrate described in Japanese Unexamined Patent Application Publication No. 2014-149410. The display substrate described in Japanese Unexamined Patent Application Publication No. 2014-149410 includes a plurality of pixel electrodes, a signal supply unit (display signal driving circuit) that supplies image signals (display signals) to the plurality of pixel electrodes, and a plurality of source wires through which the images signals are transmitted from the signal supply unit separately to each of the plurality of pixel electrodes.

There has also been known a display substrate in which a demultiplexer circuit constituted by a plurality of thin-film transistors is interposed between a plurality of source wires and a signal supply unit. By using the demultiplexer circuit to distribute, to the plurality of source wires, image signals supplied from the signal supply unit, the total number of wires that connect the signal supply unit and the demultiplexer circuit to each other can be made smaller than the total number of source wires. This makes it possible to easily route the wires on the display substrate. However, in a case where the image signals are distributed to the plurality of source wires, time-division control is exercised, so that charging and discharging of each pixel electrode needs to be completed in a shorter period of time. For this reason, a higher positive bias needs to be applied to each of the thin-film transistors constituting the demultiplexer circuit. This causes a rise (positive shift) in threshold voltage of the thin-film transistor, resulting in a decrease in an on-state current that is obtained at a prescribed operating potential. Note that a possible cause of the rise in threshold voltage of the thin-film transistor is that an electron trapped at a level that is present, for example, inside a semiconductor component constituting the thin-film transistor weakens a positive electric field from a gate electrode.

It is desirable to ensure an on-state current of each thin-film transistor constituting a demultiplexer circuit.

### SUMMARY

According to an aspect of the disclosure, there is provided a display substrate including a plurality of first wires extending in a first direction, a plurality of second wires extending in a second direction intersecting the first direction, a plurality of first thin-film transistors each connected to any of the plurality of first wires and any of the plurality of second wires, a plurality of pixel electrodes arranged in a matrix in the first direction and the second direction and each connected to a corresponding one of the plurality of first thin-film transistors, a signal supply unit that supplies image signals to the plurality of second wires, and a plurality of second thin-film transistors constituting a demultiplexer circuit that distributes, to the plurality of second wires, the image signals supplied from the signal supply unit. Each of the first thin-film transistors includes a first gate electrode connected to a corresponding one of the first wires and a first semiconductor component placed opposite the first electrode across a first insulating film. Each of the second thin-film transistors includes a second gate electrode having a gate length that is smaller than a gate length of the first gate electrode, a second semiconductor component placed opposite the second gate electrode across the first insulating film, and a third gate electrode placed at a side of the second semiconductor component that faces away from the second gate electrode and placed opposite the second semiconductor component across a second insulating film.

According to an aspect of the disclosure, there is provided a display device including the display substrate and a counter substrate placed opposite the display substrate.

### BRIEF DESCRIPTION OF THE DRAWINGS

FIG. 1 is a cross-sectional view of a liquid crystal panel, a driver, and a flexible substrate according to Embodiment 1;

FIG. 2 is a circuit diagram showing an electrical configuration of the liquid crystal panel according to Embodiment 1;

FIG. 3 is a cross-sectional view showing an array substrate according to Embodiment 1;

FIG. 4 is a cross-sectional view showing an array substrate according to Embodiment 2; and

FIG. 5 is a cross-sectional view showing an array substrate according to Embodiment 3.

### DESCRIPTION OF THE EMBODIMENTS

### Embodiment 1

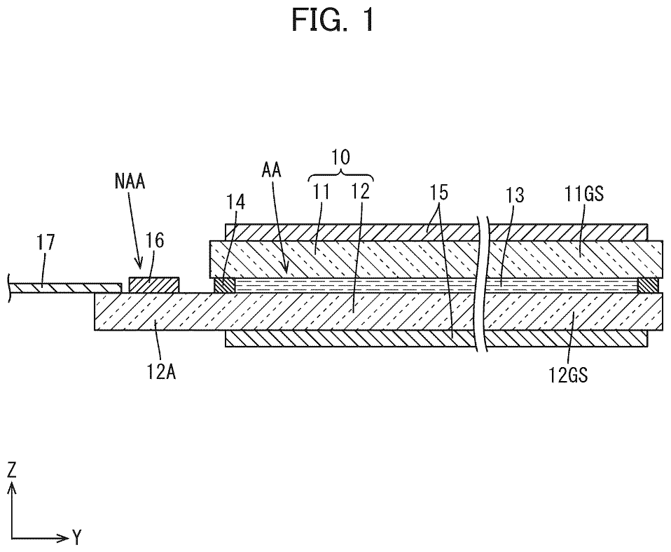

Embodiment 1 of the present disclosure is described with reference to FIGS. 1 to 3. In the present embodiment, a liquid crystal panel 10 is illustrated as a display device, and an array substrate 12 that the liquid crystal panel 10 includes is illustrated as a display substrate. Note that some of the drawings show an X axis, a Y axis, and a Z axis and are drawn so that the direction of each axis is an identical direction in each drawing. Note that the liquid crystal panel 10 forms, for example, a rectangular shape in a plan view and has one side direction corresponding to an X-axis direction, another side direction corresponding to an Y-axis direction, and a board thickness direction corresponding to a Z-axis direction.

As shown in FIG. 1, the liquid crystal panel 10 includes a pair of substrates 11 and 12 and a liquid crystal layer 13 sandwiched between the pair of substrates 11 and 12. The pair of substrates 11 and 12 are substantially transparent, have superior translucency, and are made of glass. The liquid crystal layer 13 contains liquid crystal molecules constituting a substance whose optical properties change in the presence of the application of an electric field. Interposed between outer peripheral end portions of the pair of substrates 11 and 12 is a seal portion 14 that seals in the liquid crystal layer 13. The seal portion 14 is formed in the shape of a rectangular frame (endless ring) so as to surround the liquid crystal layer 13. Polarizing plates 15 are attached on outer surfaces of the substrates 11 and 12, respectively. One of the pair of substrates 11 and 12 placed forward is a counter substrate 11, and one of the pair of substrates 11 and 12 placed backward is an array substrate 12 (display substrate, active matrix substrate). The counter substrate 11 is placed opposite the array substrate 12. The counter substrate 11 and the array substrate 12 are both formed by various types of film being stacked on inner surfaces of glass substrates 11GS and 12GS, respectively.

A dimension of the array substrate 12 in the Y-axis direction is larger than a dimension of the counter substrate 11 in the Y-axis direction. The counter substrate 11 is bonded to the array substrate 12 so that a first end portion of the counter substrate 11 in the Y-axis direction is aligned with a first end portion of the array substrate 12 in the Y-axis direction. Accordingly, a second end portion of the array substrate 21 in the Y-axis direction serves as an exposed area 12A exposed by protruding laterally with respect to the counter substrate 11. On the exposed area 12A, a driver 16 (signal supply unit) and a flexible substrate 17 are mounted.

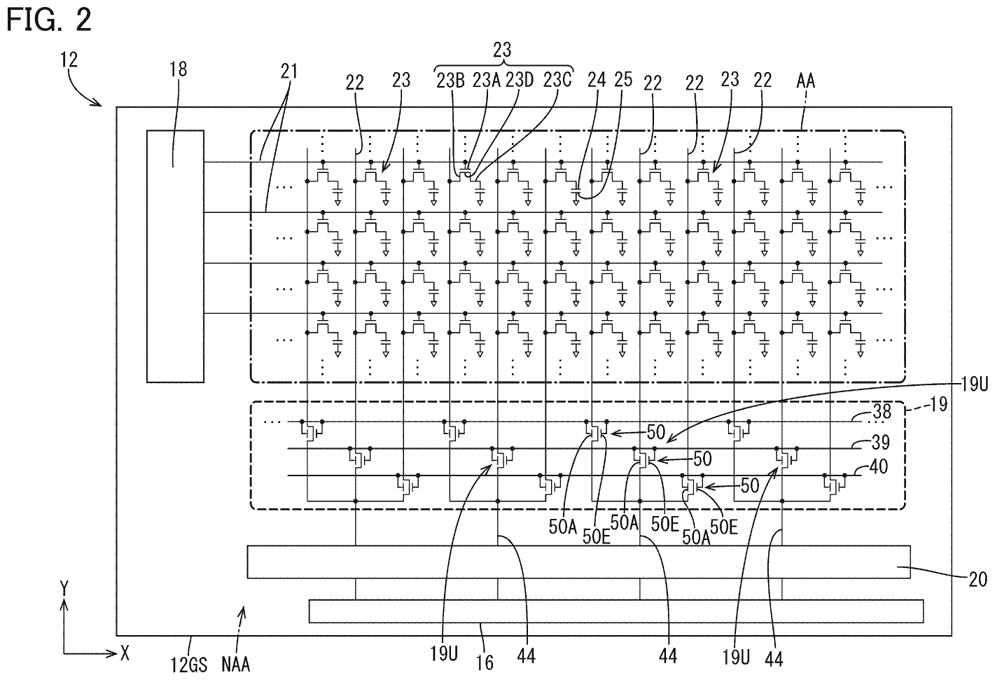

The liquid crystal panel 10 is capable of displaying an image by utilizing illuminating light emitted by a backlight device (lighting device; not illustrated). As shown in FIG. 2, the liquid crystal panel 10 includes an active area AA where an image is displayed and a non-active area NAA where no image is displayed. The active area AA occupies a large portion of a center side of a screen, and the non-active area NAA is placed in a frame-shaped outer peripheral portion surrounding the active area AA. For a detailed illustration of the demultiplexer circuit 19 in the non-active area NAA, the proportion of the non-active area NAA to the active area AA in FIG. 2 is larger than it actually is.

The driver 16 is composed of an LSI chip having a driving circuit inside. The driver 16 is mounted by COG (chip on glass) on the exposed area 12A of the array substrate 12. The driver 16 processes various types of signal that are transmitted by the flexible substrate 17. The driver 16 is configured to supply various types of signal to various types of wire that the array substrate 12 includes and, for example, is configured to supply image signals to a plurality of source wires 22. The flexible substrate 17 includes a base material composed of a synthetic resin material (such as polyimide resin) having insulating properties and flexibility and a large number of wiring patterns formed on the base material. As shown in FIG. 1, the flexible substrate 17 has a first end connected to the exposed area 12A of the array substrate 12. More specifically, the flexible substrate 17 is connected to an end portion of the exposed area 12A opposite the active area AA in the Y-axis direction behind the driver 16. Further, the flexible substrate 17 has a second end connected to an external circuit substrate (such as a control substrate; not illustrated).

In the non-active area NAA of the array substrate 12, as shown in FIG. 2, a gate driving circuit 18, the demultiplexer circuit 19, and a protective circuit 20 are provided. The gate driving circuit 18 is provided in such a manner as to extend along one side direction (Y-axis direction) of the array substrate 12. The gate driving circuit 18 is intended to supply scanning signals to the after-mentioned gate wires 21, and is monolithically provided on the glass substrate 12GS of the array substrate 12.

As shown in FIG. 2, the demultiplexer circuit 19 and the protective circuit 20 are placed in a position in the non-active area NAA situated between the active area AA and the driver 16 in the Y-axis direction. The demultiplexer circuit 19 and the protective circuit 20 are both provided in such a manner as to extend along another side direction (X-axis direction) of the array substrate 12. The demultiplexer circuit 19 is located closer to the active area AA (farther away from the driver 16) than the protective circuit 20 in the Y-axis direction. The demultiplexer circuit 19 has a function of sorting, to the after-mentioned plurality of source wires 22, image signals supplied from the driver 16. A specific configuration of the demultiplexer circuit 19 will be described in detail later. The protective circuit 20 is located farther away from the active area AA (closer to the driver 16) than the demultiplexer circuit 19 in the Y-axis direction. The protective circuit 20 has a function of protecting, from a surge, components (the driver 16, the source wires 22, and switch TFTs 50 and pixel TFTs 23 of the demultiplexer circuit 19) connected to source trunk wires 44.

On an inner surface of the array substrate 12 in the active area AA, as shown in FIG. 2, a gate wire 21 (first wire) and a source wire 22 (second wire) intersecting each other are provided. The gate wire 21 extends in the X-axis direction (first direction) in such a manner as to traverse the active area AA, and a plurality of the gate wires 21 are placed side by side at spacings in the Y-axis direction. The source wire 22 extends in the Y-axis direction (second direction intersecting the first direction) in such a manner as to traverse longitudinally the active area AA, and a plurality of the source wires 22 are placed side by side at spacings in the X-axis direction. On the inner surface of the array substrate 12 in the active area AA, a pixel TFT 23 (first thin-film transistor) and a pixel electrode 24 are provided in an area surrounded by the gate wire 21 and the source wire 22.

A plurality of the pixel TFTs 23 and a plurality of the pixel electrodes 24 are provided in a matrix (rows and columns) in the X-axis direction and the Y-axis direction. The plurality of pixel TFTs 23 are each connected to any of the plurality of gate wires 21 and any of the plurality of source wires 22. Each of the plurality of pixel electrodes 24 is connected to a corresponding one of the plurality of pixel TFTs 23. Each of the pixel TFTs 23 includes a gate electrode 23A connected to a corresponding one of the gate wires 21, a source electrode 23B connected to a corresponding one of the source wires 22, a drain electrode 23C connected to a corresponding one of the pixel electrodes 24, and a semiconductor component 23D connected to the source electrode 23B and the drain electrode 23C. The pixel TFT 23 is driven in accordance with a scanning signal supplied to the gate wire 21, and then the pixel electrode 24 is charged to a potential based on an image signal (data signal) supplied to the source wire 22.

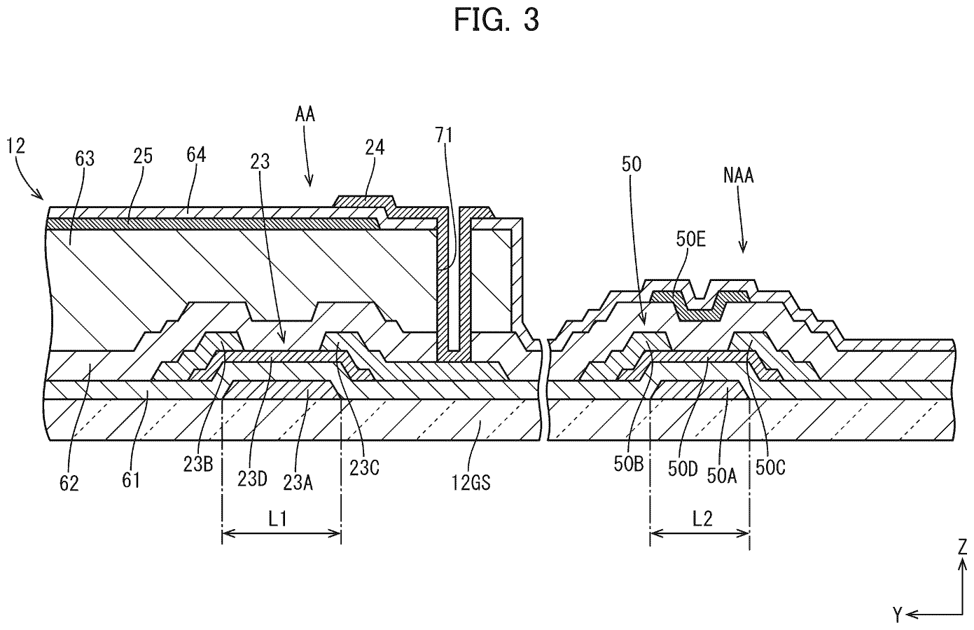

Further, on an inner surface of the counter substrate 11 in the active area AA, color filters of three colors placed in such a manner as to overlap each pixel electrode 24 and taking on red (R), green (G), and blue (B), a light-blocking component (black matrix), or other components are provided. In the liquid crystal panel 10, R, G, and B color filters arranged along the X-axis direction and three pixel electrodes 24 separately facing each of the color filters constitute a pixel. The pixel is a display unit in the active area AA, and a plurality of the pixels are arrayed at predetermined array pitches in the X-axis direction and the Y-axis direction. Further, as shown in FIG. 3, the array substrate 12 is provided with a common electrode 25 composed of a transparent electrode material that is similar to that of the pixel electrodes 24 and disposed to overlap the pixel electrodes 24 at a spacing from the pixel electrodes 24. The liquid crystal panel 10 is capable of causing each pixel to perform a predetermined gradation display in the presence of the application of a predetermined electric field to the liquid crystal layer 13 on the basis of a potential difference generated between the common electrode 25 and each pixel electrode 24.

Next, a configuration of the demultiplexer circuit 19 is described. The demultiplexer circuit 19 is a so-called SSD (source shared driving) circuit. As shown in FIG. 2, the demultiplexer circuit 19 includes a plurality of unit switch circuit components 19U arranged along a direction of the length thereof (substantially along the X-axis direction) and three switch wires 38 to 40 through which switching switch signals are transmitted. Each of the unit switch circuit components 19U has three switch TFTs 50. The three switch TFTs 50 are each connected to any of the switch wires 38 to 40 and to a corresponding one of the source wires 22 and have a function of controlling the supply of image signals. The number of unit switch circuit components 19U that are provided is ⅓ of the number of source wires 22 that are provided.

The three switch wires 38 to 40 are placed at spacings in the Y-axis direction and each extend along the X-axis direction. Although not illustrated, each of the switch wires 38 to 40 is connected to the driver 16. The switch wires 38 to 40 are a red switch wire 38, a green switch wire 39, and a blue switch wire 40 in this order from the top of FIG. 2. Each of the switch TFTs 50 (second thin-film transistor) is, for example, an N-channel transistor.

Of the three switch TFTs 50 that constitute a unit switch circuit component 19U, the switch TFT 50 placed on the left side of FIG. 2 is a red switch TFT whose gate electrodes 50A and 50E (which will be described in detail later) are connected to the red switch wire 38 and whose drain electrode 50C (see FIG. 3) is connected to a source wire 22 through which an image signal is supplied to a pixel electrode 24 that constitutes a red pixel. Of the three switch TFTs 50 that constitute a unit switch circuit component 19U, the switch TFT 50 placed on the center side of FIG. 2 is a green switch TFT whose gate electrodes 50A and 50E are connected to the green switch wire 39 and whose drain electrode 50C is connected to a source wire 22 through which an image signal is supplied to a pixel electrode 24 that constitutes a green pixel. Of the three switch TFTs 50 that constitute a unit switch circuit component 19U, the switch TFT 50 placed on the right side of FIG. 2 is a blue switch TFT whose gate electrodes 50A and 50E are connected to the blue switch wire 40 and whose drain electrode 50C is connected to a source wire 22 through which an image signal is supplied to a pixel electrode 24 that constitutes a blue pixel.

Each of the switch TFTs 50 has its source electrode 50B (see FIG. 3) connected to a corresponding one of the source trunk wires 44 provided in the non-active area NAA of the array substrate 12. Each of the source trunk wires 44 has its first end connected to the driver 16 and has its second end divided into three parts connected separately to each of the source electrodes of the three switch TFTs 50. The number of source trunk wires 44 that are provided is ⅓ of the number of source wires 22 that are provided. In this way, the number of wires that are present between the driver 16 and the demultiplexer circuit 19 can be reduced to ⅓ as compared with a case where the source wires 22 are directly connected to the driver 16. This makes it possible to easily route the wires (source trunk wires 44) even in a case where there is further narrowing of the frame of the liquid crystal panel 10.

A red image signal for use in a red pixel, a green image signal for use in a green pixel, and a blue image signal for use in a blue pixel are supplied from the driver 16 to each of the source trunk wires 44 in a time-division manner. In synchronization with these image signals, switch signals are supplied from the driver 16 to the three switch wires 38 to 40. Specifically, at a timing when the red image signal is supplied from the driver 16 to the source trunk wire 44, a switch signal is supplied from the driver 16 to the red switch wire 38. This selectively brings the red switch TFT 50 into an on state, thus making it possible to supply the red image signal via a selected source wire 22 to a pixel electrode 24 that constitutes a red pixel.

Further, at a timing when the green image signal is supplied from the driver 16 to the source trunk wire 44, a switch signal is supplied from the driver 16 to the green switch wire 39. This selectively brings the green switch TFT 50 into an on state, thus making it possible to supply the green image signal via a selected source wire 22 to a pixel electrode 24 that constitutes a green pixel.

Further, at a timing when the blue image signal is supplied from the driver 16 to the source trunk wire 44, a switch signal is supplied from the driver 16 to the blue switch wire 40. This selectively brings the blue switch TFT 50 into an on state, thus making it possible to supply the blue image signal via a selected source wire 22 to a pixel electrode 24 that constitutes a blue pixel. As noted above, the demultiplexer circuit 19 makes it possible to, in synchronization with the timing of supply of image signals from the driver 16 to the source trunk wire 44, switch between connecting one source wire 22 to the source trunk wire 44 and connecting another source wire 22 to the source trunk wire 44.

Next, various types of film that are stacked on the glass substrate 12GS of the array substrate 12 are described with reference to FIG. 3. FIG. 3 is a diagram showing a cross-sectional configuration of a pixel 23 and a switch TFT 50 in the array substrate 12. On the glass substrate 12GS of the array substrate 12, as shown in FIG. 3, a first metal film, a first insulating film 61 (gate insulating film), a semiconductor film, a second metal film, a second insulating film 62 (passivation film), a third insulating film 63, a first transparent conductive film, a fourth insulating film 64, and a second transparent conductive film are stacked in this from the bottom (i.e. from the glass substrate 12GS).

The first and second metal films have electrical conductivity and a light blocking effect and are both constituted by a single-layer film composed of one type of metallic material (such as copper (Cu), titanium (Ti), aluminum (Al), molybdenum (Mo), and tungsten (W)) or a laminated film or an alloy composed of different types of metallic material. The first and second transparent conductive films are composed of a transparent electrode material such as ITO (indium tin oxide) or IZO (indium zinc oxide).

The first insulating film 61 and the fourth insulating film 64 are constituted, for example, by silicon nitride (SiNₓ) or silicon oxide (SiO₂). The second insulating film 62 is constituted by an inorganic insulating film of, for example, silicon nitride or silicon oxide as well as an acrylic resin film (such as polymethyl methacrylate resin (PMMA)). The third insulating film 63 is composed of, for example, PMMA (acrylic resin), which is a type of organic material (organic resin material). The third insulating film 63 is, for example, set greater in film thickness than the first insulating film 61, the second insulating film 62, and the fourth insulating film 64.

The semiconductor film is composed of an oxide semiconductor material. The semiconductor film may contain at least one of metallic elements In, Ga, and Zn and, for example, may be an In—Ga—Zn—O semiconductor (e.g. indium-gallium-zinc oxide). The In—Ga—Zn—O semiconductor here is a ternary oxide of In (indium), Ga (gallium), and Zn (zinc), and the proportions (composition ratios) of In, Ga, and Zn are not limited to particular values. Examples of the proportions include In:Ga:Zn=2:2:1, In:Ga:Zn=1:1:1, and In:Ga:Zn=1:1:2. The In—Ga—Zn—O semiconductor for use in the semiconductor film may be amorphous or may be crystalline.

The semiconductor film may contain another oxide semiconductor instead of the In—Ga—Zn—O semiconductor. For example, the semiconductor film may contain an In—Sn—Zn—O semiconductor (e.g. In₂O₃-SnO₂-ZnO; InSnZnO). The In—Sn—Zn—O semiconductor is a ternary oxide of In (indium), Sn (tin), and Zn (zinc). Alternatively, the oxide semiconductor layer 4 may contain an In—W—Zn—O semiconductor containing W (tungsten), an In—W—Sn—Zn—O semiconductor, an In—Al—Zn—O semiconductor, an In—Al—Sn—Zn—O semiconductor, a Zn—O semiconductor, an In—Zn—O semiconductor, a Zn—Ti—O semiconductor, a Cd—Ge—O semiconductor, a Cd—Pb—O semiconductor, CdO (cadmium oxide), a Mg—Zn—O semiconductor, an In—Ga—Sn—O semiconductor, an In—Ga—O semiconductor, a Zr—In—Zn—O semiconductor, a Hf—In—Zn—O semiconductor, an Al—Ga—Zn—O semiconductor, a Ga—Zn—O semiconductor, an In—Ga—Zn—Sn—O semiconductor, or other semiconductors.

The pixel TFT 23 includes a gate electrode 23A (first gate electrode) connected to a gate wire 21, a source electrode 23B, a drain electrode 23C, and a semiconductor component 23D (first semiconductor component). The semiconductor component 23D is constituted by the aforementioned semiconductor film and placed opposite the gate electrode 23A across the first insulating film 61.

The gate electrode 23A is composed of the first metal film and placed on top of the glass substrate 12GS. The gate electrode 23A is placed at a lower layer than the semiconductor component 23D and overlap a central portion of the semiconductor component 23D in the Y-axis direction. The source electrode 23B and the drain electrode 23C are constituted by the second metal film. The source electrode 23B is placed in such a manner as to be connected to a first end portion of the semiconductor component 23D in the Y-axis direction. The drain electrode 23C is placed in such a manner as to be connected to a second end portion of the semiconductor component 23D in the Y-axis direction.

In the active area AA, the pixel electrodes 24 and the common electrode 25 are placed. The common electrode 25 is composed of the first transparent conductive film. The common electrode 25 is placed substantially all over the active area AA. With this, the common electrode 25 is placed at a lower layer than all pixel electrodes 24 placed in the active area AA and overlaps the pixel electrodes 24 via the fourth insulating film 64. A plurality of slits are bored through portions of the common electrode 25 that overlap the plurality of pixel electrodes 24. Each of the pixel electrodes 24 is composed of the second transparent conductive film. A contact hole 71 is provided in the insulating films 62, 63, and 64 interposed between the pixel electrode 24 and the drain electrode 23C. The contact hole 71 is placed in such a position as to overlap the pixel electrode 24 and the drain electrode 23C. The pixel electrode 24 is connected to the drain electrode 23C through the contact hole 71.

The common electrode 25 is supplied with a common potential signal that is at a common potential (reference potential). When the pixel TFT 23 is driven and then the pixel electrode 24 is charged to a potential based on an image signal transmitted to the source wire 22, there occurs a potential difference between the pixel electrode 24 and the common electrode 25. Then, a fringe field (oblique field) including a component acting along a board surface of the array substrate 12 and a component acting in a direction normal to the board surface of the array substrate 12 is generated between an opening edge of a corresponding one of the slits in the common electrode 25 and the pixel electrode 24. Accordingly, utilizing this fringe field makes it possible to control a state of alignment of the liquid crystal molecules contained in the liquid crystal layer 13, and a predetermined display is performed on the basis of this state of alignment of the liquid crystal molecules. That is, the liquid crystal panel 10 according to the present embodiment operates in an FFS (fringe field switching) mode.

In the non-active area NAA, the switch TFTs 50 are placed. As shown in FIG. 3, each of the switch TFTs 50 includes a gate electrode 50A (second gate electrode), a source electrode 50B, a drain electrode 50C, a semiconductor component 50D (second semiconductor component), and a gate electrode 50E (third gate electrode). The gate electrode 50A is composed of the first metal film and placed on top of the glass substrate 12GS. Since the gate electrode 23A and the gate electrode 50A are both composed of the same metal film (first metal film), the layer number of metal films can be reduced as compared with a case where the gate electrode 23A and the gate electrode 50A are constituted by different metal films.

The gate electrode 50A is placed at a lower layer than the semiconductor component 50D and overlaps a central portion of the semiconductor component 50D in the Y-axis direction. The source electrode 50B and the drain electrode 50C are constituted by the second metal film. The source electrode 50B is placed in such a manner as to be connected to a first end portion of the semiconductor component 50D in the Y-axis direction. The drain electrode 50C is placed in such a manner as to be connected to a second end portion of the semiconductor component 50D in the Y-axis direction. The semiconductor component 50D is constituted by the semiconductor film as is the case with the semiconductor component 23D and placed opposite the gate electrode 50A across the first insulating film 61. The gate electrode 50A has a gate length L2 that is smaller than a gate length L1 of the gate electrode 23A.

The gate electrode 50E is placed at a side of the semiconductor component 50D that faces away from the gate electrode 50A and placed opposite the semiconductor component 50D across the second insulating film 62. The semiconductor component 50D is sandwiched between the gate electrode 50A situated below the semiconductor component 50D and the gate electrode 50E situated above semiconductor component 50D. That is, the switch TFT 50 has a double-gate structure. In the non-active area NAA, the third insulating film 63 is not interposed between the second insulating film 62 and the fourth insulating film 64, so that the gate electrode 50E is placed on top of the second insulating film 62.

The gate electrode 50E is constituted by the first transparent conductive film. That is, the gate electrode 50E is constituted by the same material as the common electrode 25 (i.e. the transparent conductive film placed at a side of the second insulating film 62 at which the gate electrode 50E is placed). When switch signals are supplied from the driver 16 to the gate electrode 50A and the gate electrode 50E via switch wires (any of the switch wires 38 to 40), electric fields acting on the semiconductor component 50D from the gate electrode 50A and the gate electrode 50E form channel regions in a portion of the semiconductor component 50D that faces a lower layer (i.e. the gate electrode 50A) and a portion of the semiconductor component 50D that faces an upper layer (i.e. the gate electrode 50E). This makes it possible to cause the channel regions to be stably formed in the semiconductor component 50D.

Next, effects of the present embodiment are described. According to the present embodiment, by using the demultiplexer circuit 19 to distribute image signals to the plurality of source wires 22, the total number of source trunk wires 44 that connect the driver 16 and the demultiplexer circuit 19 to each other can be made smaller than the total number of source wires 22. This makes it possible to easily route the source trunk wires 44 on the array substrate 12.

Further, each of the switch TFTs 50 constituting the demultiplexer circuit 19 includes a gate electrode 50A and a gate electrode 50E between which a semiconductor component 50D sandwiched. Such a double gate structure makes it possible to form channel regions at both sides of the semiconductor component 50D, making it possible to further increase the on-state current of the switch TFT 50. Furthermore, the gate electrode 50A has a gate length L2 that is smaller than a gate length L1 of the gate electrode 23A. This makes it possible to make the on-state current of the switch TFT 50 higher than it is in a case where the gate length L2 of the gate electrode 50A is equal to the gate length L1 of the gate electrode 23A. All this makes it possible to ensure an on-state current in each of the switch TFTs 50 constituting the demultiplexer circuit 19.

Further, the common electrode 25 is placed at a side of the second insulating film 62 at which the gate electrode 50E is placed, and the gate electrode 50E is constituted by a material (first transparent conductive film) that is identical to that of the common electrode 25. Placing the gate electrode 50E and the common electrode 25 at the same side of the second insulating film 62 and making the gate electrode 50E and the common electrode 25 of the same material makes it possible to form the gate electrode 50E and the common electrode 25 at the same time, making it possible to simplify a manufacturing process.

### Embodiment 2

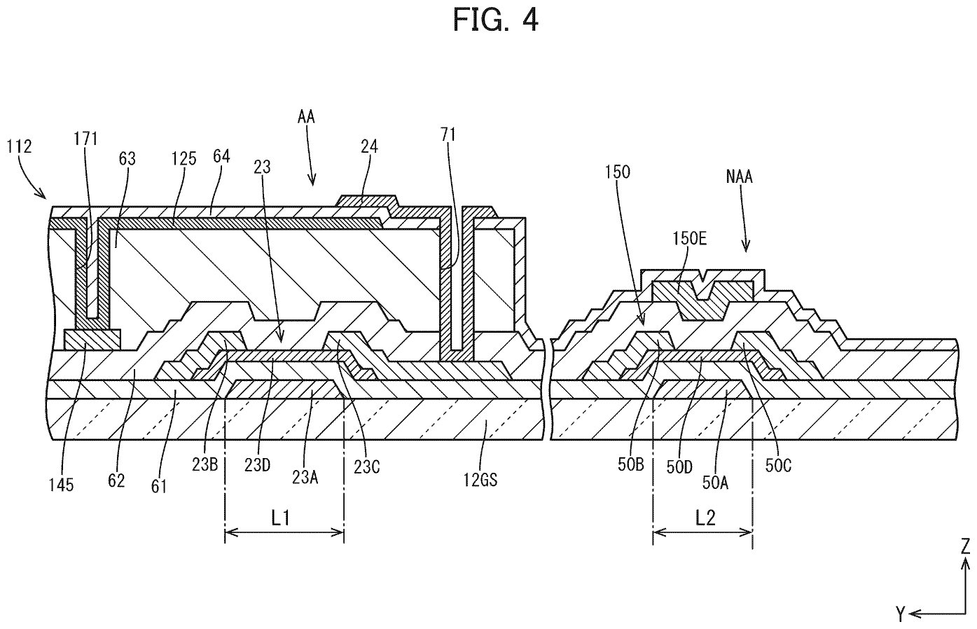

Embodiment 2 of the present disclosure is described with reference to FIG. 4. Components that are identical to those of the foregoing embodiment are given identical reference signs, and a repeated description of such components is omitted. An array substrate 112 of the present embodiment differs from the foregoing embodiment in configuration of various types of film stacked on top of the glass substrate 12GS. The array substrate 112 has a touch panel pattern for fulfilling a touch panel function. The touch panel pattern is of a so-called projected capacitive type, and its detecting scheme is a self-capacitance scheme. The touch panel pattern is constituted by a position detection electrode 125 shown in FIG. 4. The position detection electrode 125 is constituted by a transparent conductive film (more specifically the aforementioned first transparent conductive film), and a plurality of the position detection electrodes 125 are arranged in a matrix in the active area AA of the liquid crystal panel 10.

When a user of the liquid crystal panel 10 moves a finger as a conductor toward a surface of the liquid crystal panel 10 in an attempt to input a position on the basis of an image in the active area AA, a capacitance is formed between the position-inputting finger (position input body) and the position detection electrode 125. With this, a capacitance detected by a position detection electrode 125 situated near the finger undergoes a change as the finger approaches, and becomes different from that detected by a position detection electrode 125 situated away from the finger, so that it becomes possible to detect an input position accordingly. The position detection electrode 125 forms a substantially rectangular shape in a plan view. The size of one position detection electrode 125 is larger than that of one pixel electrode 24. The position detection electrode 125 is placed in an area over a plurality of pixel electrodes 24 in planar directions (X-axis and Y-axis directions).

As shown in FIG. 4, a position detection wire 145, connected to the position detection electrode 125, through which a position detection signal is transmitted is formed on top of the second insulating film 62. Each of the plurality of position detection electrodes 125 is connected to a corresponding one of a plurality of the position detection wires 145. The third insulating film 63 interposed between the position detection electrode 125 and the position detection wire 145 is provided with a contact hole 171. The contact hole 171 is placed in such a position as to overlap the position detection electrode 125 and the position detection wire 145. The position detection electrode 125 is connected to the position detection wire 145 through the contact hole 171. The position detection wire 145 runs parallel to the source wires 22 (see FIG. 2) and is connected to the driver 16 at an end portion thereof that faces away from the position detection electrode 125.

A common potential signal pertaining to a display function and a position detection signal pertaining to a touch function are supplied from the driver 16 to the position detection wire 145 at different timings (i.e. in a time-division manner). The timing at which the common potential signal is supplied from the driver 16 to the position detection wire 145 is a display period, and the timing at which the position detection signal is supplied from the driver 16 to the position detection wire 145 is a sensing period (position detection period). Since, in the display period, the common potential signal is supplied to all position detection wires 145, all position detection electrodes 125 are brought to a reference potential and function as a common electrode.

A switch TFT 150 (second thin-film transistor) includes a gate electrode 50A, a source electrode 50B, a drain electrode 50C, a semiconductor component 50D, and a gate electrode 150E (third gate electrode). The gate electrode 150E is placed at a side of the semiconductor component 50D that faces away from the gate electrode 50A and placed opposite the semiconductor component 50D across the second insulating film 62. The position detection wire 145 is placed at a side of the second insulating film 62 at which the gate electrode 150E is placed, and is constituted by a material (third metal film) that is identical to that of the gate electrode 150E. The third metal film constituting the position detection wire 145 and the gate electrode 150E is constituted by a single-layer film composed of one type of metallic material (such as copper (Cu), titanium (Ti), aluminum (Al), molybdenum (Mo), and tungsten (W)) or a laminated film or an alloy composed of different types of metallic material.

Placing the gate electrode 150E and the position detection wire 145 at the same side of the second insulating film 62 and making the gate electrode 150E and the position detection wire 145 of the same material makes it possible to form the gate electrode 150E and the position detection wire 145 at the same time, making it possible to simplify a manufacturing process. Further, since, unlike the position detection electrode 125, which is formed over a comparatively large area, the position detection wire 145 does not need to be constituted by a transparent conductive film, the position detection wire 145 can be made of a material that is lower in electric resistance than a transparent conductive film. This makes it possible to further lower electric resistance of the gate electrode 150E, making it possible to suppress a signal delay.

### Embodiment 3

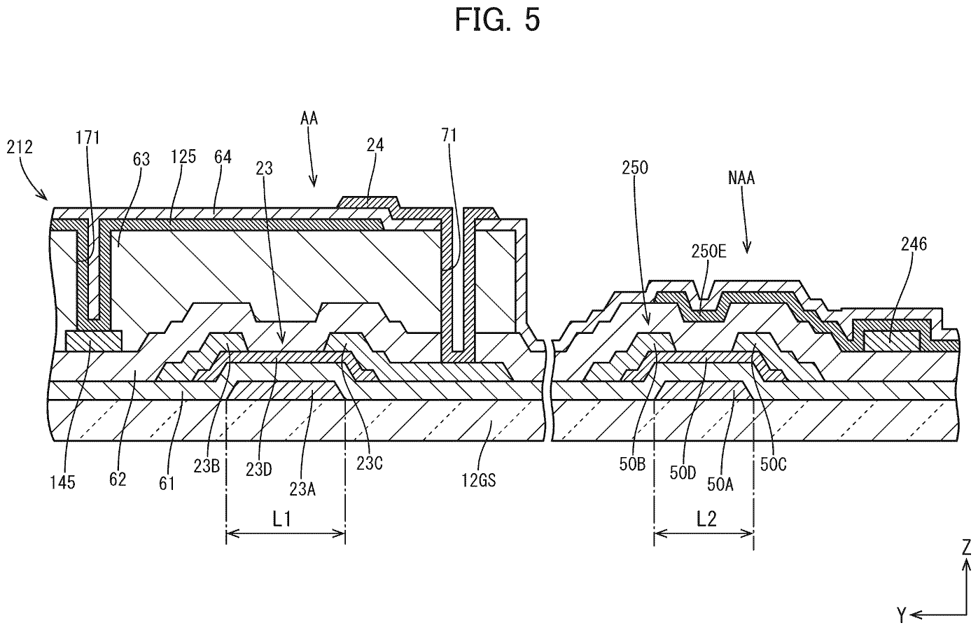

Embodiment 3 of the present disclosure is described with reference to FIG. 5. An array substrate 212 of the present embodiment differs from the foregoing embodiment in configuration of a switch TFT 250 (second thin-film transistor). As shown in FIG. 5, the switch TFT 250 includes a gate electrode 50A, a source electrode 50B, a drain electrode 50C, a semiconductor component 50D, and a gate electrode 250E (third gate electrode). Further, a switch wire 246 (gate electrode wire) connected to the gate electrode 250E is formed on top of the second insulating film 62. The switch wire 246 is used as any of the red, green, and blue switch wires described in the foregoing embodiment.

The gate electrode 250E is placed at a side of the second insulating film 62 at which the position detection electrode 125 is placed, and is constituted by a material (i.e. the aforementioned first transparent conductive film) that is identical to that of the position detection electrode 125. The switch wire 246 is placed at a lower layer than the gate electrode 250E. Further, the switch wire 246 is placed at a side of the second insulating film 62 at which the position detection wire 145 is placed, and is constituted by a material (i.e. the aforementioned third metal film) that is identical to that of the position detection wire 145. Further, the gate electrode 50A is connected to the switch wire 246 via a contact hole (not illustrated). The switch wire 246 is provided in such a manner as not to cover a side of the semiconductor component 50D that faces away from the gate electrode 50A.

The switch wire 246 is connected to the driver 16 (see FIG. 2) at an end portion thereof that faces away from the gate electrode 250E. When switch signals are supplied from the driver 16 to the gate electrode 50A and the gate electrode 250E via the switch wires 246, electric fields acting on the semiconductor component 50D from the gate electrode 50A and the gate electrode 250E form channel regions in a portion of the semiconductor component 50D that faces a lower layer (i.e. the gate electrode 50A) and a portion of the semiconductor component 50D that faces an upper layer (i.e. the gate electrode 250E), whereby the switch TFT 250 is turned on.

The present embodiment makes it possible to form the gate electrode 250E and the position detection electrode 125 at the same time, making it possible to form the position detection wire 145 and the switch wire 246 at the same time. This makes it possible to simplify a manufacturing process. The constitution by a transparent conductive film of the gate electrode 250E covering the semiconductor component 50D of the switch TFT 250 makes it possible to inhibit stray light (i.e. light generated by reflection and refraction inside the liquid crystal panel 10) having reached the array substrate 212 from being blocked by the gate electrode 250E, allowing more light to reach the semiconductor component 50D. This makes it possible to achieve a decrease (negative shift) in threshold voltage of the switch TFT 250, making it possible to inhibit a decrease in an on-state current obtained at a prescribed operating potential.

Further, since, unlike the position detection electrode 125, the position detection wire 145 does not need to be constituted by a transparent conductive film, the position detection wire 145 can be made of a material that is lower in electric resistance than a transparent conductive film. The switch wire 246 is made of a material that is identical to that of the position detection wire 145. This makes it possible to further lower electric resistance of the switch wire 246, thus making it possible to suppress a delay in a switch signal that is transmitted to the gate electrode 250E via the switch wire 246.

### Other Embodiments

The present disclosure is not limited to the embodiments described above with reference to the drawings. The following embodiments may be included in the technical scope of the present disclosure.
(1) Although, in each of the foregoing embodiments, the electrodes (gate electrodes, source electrode, and drain electrodes) illustrated of the pixel TFTs and the switch TFTs are constituted by metal films, this is not intended to impose any limitation, and these electrodes can also be made of conductive films (such as low-resistance films obtained by subjecting semiconductor films to a resistance lowering process and transparent conductive films) other than metal films.
(2) The planar shape of the liquid crystal panel 10 is not limited to a rectangular shape but may be a circle, a semicircle, an oval, an ellipse, a trapezoid, or other shapes.
(3) Although, in each of the foregoing embodiments, the liquid crystal panel 10 has been illustrated as a display device, the liquid crystal panel 10 may be replaced by an organic EL display device, i.e. a self-luminous display device.

The present disclosure contains subject matter related to that disclosed in Japanese Priority Patent Application JP 2024-065377 filed in the Japan Patent Office on Apr. 15, 2024, the entire contents of which are hereby incorporated by reference.

It should be understood by those skilled in the art that various modifications, combinations, sub-combinations and alterations may occur depending on design requirements and other factors insofar as they are within the scope of the appended claims or the equivalents thereof.

### Cross-Reference to Related Applications

The present application claims priority from Japanese Application JP2024-065377, the content of which is hereby incorporated by reference into this application.

What is claimed is:

1. A display substrate comprising:
a plurality of first wires extending in a first direction;
a plurality of second wires extending in a second direction intersecting the first direction;
a plurality of first thin-film transistors each connected to any of the plurality of first wires and any of the plurality of second wires;
a plurality of pixel electrodes arranged in a matrix in the first direction and the second direction and each connected to a corresponding one of the plurality of first thin-film transistors;
a signal supply unit that supplies image signals to the plurality of second wires; and
a plurality of second thin-film transistors constituting a demultiplexer circuit that distributes, to the plurality of second wires, the image signals supplied from the signal supply unit, wherein
each of the first thin-film transistors includes
a first gate electrode connected to a corresponding one of the first wires, and
a first semiconductor component placed opposite the first electrode across a first insulating film, and
each of the second thin-film transistors includes
a second gate electrode having a gate length that is smaller than a gate length of the first gate electrode,
a second semiconductor component placed opposite the second gate electrode across the first insulating film, and
a third gate electrode placed at a side of the second semiconductor component that faces away from the second gate electrode and placed opposite the second semiconductor component across a second insulating film.

2. The display substrate according to claim 1, further comprising a transparent conductive film placed at a side of the second insulating film at which the third gate electrode is placed,
wherein the third gate electrode is constituted by a material that is identical to that of the transparent conductive film.

3. The display substrate according to claim 1, further comprising:
a position detection electrode, constituted by a transparent conductive film, that forms a capacitance with a position input body that performs position input; and
a position detection wire, connected to the position detection electrode, through which a position detection signal is transmitted,
wherein the position detection wire is placed at a side of the second insulating film at which the third gate electrode is placed, and is constituted by a material that is identical to that of the third gate electrode.

4. The display substrate according to claim 1, further comprising:
a position detection electrode, constituted by a transparent conductive film, that forms a capacitance with a position input body that performs position input;
a position detection wire, connected to the position detection electrode, through which a position detection signal is transmitted; and
a gate electrode wire connected to the third gate electrode,
wherein
the third gate electrode is placed at a side of the second insulating film at which the position detection electrode is placed, and is constituted by a material that is identical to that of the position detection electrode, and
the gate electrode wire is placed at a side of the second insulating film at which the position detection wire is placed, and is constituted by a material that is identical to that of the position detection wire.

5. A display device comprising:
play substrate according to claim 1; and
a counter substrate placed opposite the display substrate.
